(19) United States
(12) Patent Application Publication
(10) Pub. No.: US 2013/0112234 A1
(43) Pub. Date: May 9, 2013

(54) SOLAR CELL MODULE

(71) Applicant: Sanyo Electric Co., Ltd., Osaka (JP)

(72) Inventor: Yousuke Ishii, Osaka (JP)

(73) Assignee: Sanyo Electric Co., Ltd., Osaka (JP)

(21) Appl. No.: 13/727,563

(22) Filed: Dec. 26, 2012

Related U.S. Application Data
(63) Continuation of application No. PCT/JP2011/064243, filed on Jun. 22, 2011.

(30) Foreign Application Priority Data
Jun. 30, 2010 (JP) 2010-149372

(51) Int. Cl. H01L 31/0216

(52) U.S. Cl. CPC H01L 31/02167
USPC 136/244; 136/256

(57) ABSTRACT

A solar cell module includes solar cells and an interconnection member configured to connect the solar cells. At least one of the solar cells has a light-receiving surface including a light-receiving side electrode, a back surface including a back-side electrode, and a coating film formed on substantially the entire light-receiving surface except at least apart of the light-receiving side electrode in such a manner that the at least part is exposed from the coating film. The interconnection member is electrically connected to the part of the electrode exposed from the coating film and is mechanically connected to the coating film.

### CROSS REFERENCE TO RELATED APPLICATIONS

This application is a continuation application of International Application No. PCT/JP2011/0064243, filed on Jun. 22, 2011, entitled “SOLAR CELL MODULE”, which claims priority based on Article 8 of Patent Cooperation Treaty from prior Japanese Patent Applications No. 2010-149372, filed on Jun. 30, 2010, the entire contents of which are incorporated herein by reference.

### BACKGROUND OF THE INVENTION

1. Field of the Invention

This disclosure relates to a solar cell module and particularly relates to a solar cell module having solar cells each including a coating film on a power generation region.

2. Description of Related Art

Solar cells have been expected to be a new energy source, since the solar cells can directly convert clean and inexhaustibly-supplied sunlight into electricity.

Generally, each solar cell outputs power of only approximately several watts. Accordingly, when solar cells are used as a power source for a house, a building or the like, a solar cell module with solar cells electrically connected to one another to enhance energy output is used. The solar cell module includes solar cell strings each including the solar cells which are electrically connected to one another by using interconnection members connected to electrodes on the front and back surfaces of the solar cells.

Specifically, each solar cell string is formed in such a manner that an electrode on a light-receiving surface of one solar cell and an electrode on a back surface of another solar cell next to the one solar cell on one side hereof are electrically connected to each other by using an interconnection member.

Here, it is known that a coating film is formed on a light-receiving surface of each solar cell of the solar cell string (see Patent Document 1: Japanese Patent Application Publication No. 2007-141967, for example). In a step of forming the coating film, a transparent resin material is applied to the light-receiving surface of the solar cell placed on a placement stage.

Since the coating film is formed to protect the light-receiving surface of the solar cell from damage, moisture in the air, and the like, the resin material of the coating film is preferably applied to the entire light-receiving surface up to an outer periphery thereof.

Meanwhile, in manufacturing a solar cell module, solder is conventionally used to connect electrodes of solar cells and an interconnection member. Solder is widely used because of its high connection reliability such as conductivity and fixing strength, low cost, and general-purpose properties.

In providing the coating film, a coating material is applied to the light-receiving surface of the solar cell except a connection region on which an interconnection member is to be connected to an electrode. If the coating film is provided to the entire light-receiving surface of the solar cell and then the interconnection member is connected to the electrode by soldering, the coating film adhered to the connection region hinders electrical connection between the interconnection member and the electrode to thereby prevent current generated by the solar cell from being drawn to the outside.

For this reason, the coating material is applied to the light-receiving surface of the solar cell having a certain distance away from the electrode to which the interconnection member is to be connected, without being in contact with both side edges of the electrode.

### SUMMARY OF THE INVENTION

To provide various functions, the coating film is provided to the light-receiving surface of the solar cell. If the coating film is provided to the entire light-receiving surface, the functions can work in the entire solar cell. The coating film, however, is conventionally provided at a certain distance away from the electrode to which the interconnection member is to be connected without being in contact with the side edges of the electrode, in consideration of electrical connection between the electrode and the interconnection member as described above.

To obtain further effects of the various functions of the coating film, the coating film is desired to be formed on the entire light-receiving surface of a photoelectric conversion body of the solar cell without any gap between the coating film and the side edges of the electrode to which the interconnection member is to be connected.

An object of one embodiment of the invention is to provide a solar cell module having a coating film on an entire light-receiving surface of a photoelectric conversion body of each solar cell and making it possible to electrically connect an electrode and an interconnection member.

An aspect of the invention is a solar cell module including: solar cells; and an interconnection member configured to connect the solar cells. One of the solar cells includes: a light-receiving surface including a light-receiving side electrode, a back surface including a back-side electrode, and a coating film formed on substantially the entire light-receiving surface except at least a part of the light-receiving side electrode in such a manner that the at least part is exposed. The interconnection member is electrically connected to the part of the electrode exposed from the coating film and is mechanically connected to the coating film.

The coating film may be formed to have a film thickness less than a thickness of the electrode on the light-receiving surface. The coating film may be formed by applying a resin to the entire light-receiving surface.

The interconnection member and each solar cell may be connected to each other with a resin adhesive.

The electrode may be provided with a texture on a surface thereof, and the coating film may be formed to have a film thickness less than a height of the textured surface.

According to the aspect, the coating film is formed at least on the entire light-receiving surface of the photoelectric conversion body. Hence, various functions of the coating film can be provided for the entire light-receiving surface of the photoelectric conversion body.

### BRIEF DESCRIPTION OF THE DRAWINGS

FIG. 1 is an enlarged side cross-sectional view of a solar cell module according to a first embodiment of the invention.

FIG. 2 is a plan view of one of solar cells in a state where a coating film is yet to be formed.

FIG. 3 is a plan view of the solar cell, illustrating the coating film formed on an entire light-receiving surface of a photoelectric conversion body of the solar cell.

FIG. 4 is a cross-sectional view of the solar cell taken along the A-A′ line of FIG. 3.

FIG. 5 is a cross-sectional view of the solar cell taken along the B-B′ line of FIG. 3.

FIG. 6 is a plan view of the solar cell according to the first embodiment of the invention, illustrating a state where interconnection members are connected to the solar cell.

FIG. 7 is a schematic cross-sectional diagram of the solar cell according to the first embodiment, illustrating the state where the interconnection members are connected to the solar cell.

FIG. 8 is a plan view of the solar cells according to the first embodiment, illustrating the state where the interconnection members are connected to the solar cells.

FIG. 9 is a schematic side cross-sectional diagram illustrating the solar cells according to the first embodiment in an enlarged manner.

FIG. 10 is a schematic diagram illustrating a method of forming the coating film according to the first embodiment.

FIG. 11A is a schematic cross-sectional diagram illustrating a step of a method of manufacturing a solar cell string according to the first embodiment.

FIG. 11B is a schematic cross-sectional diagram illustrating a step of the method of manufacturing the solar cell string according to the first embodiment.

FIG. 11C is a schematic cross-sectional diagram illustrating a step of the method of manufacturing the solar cell string according to the first embodiment.

FIG. 11D is a schematic cross-sectional diagram illustrating a step of the method of manufacturing the solar cell string according to the first embodiment.

FIG. 12 is a plan view of a solar cell, illustrating that a coating film is formed on an entire surface of a light-receiving surface of a photoelectric conversion body of a solar cell according to a second embodiment of the invention.

FIG. 13 is a plan view illustrating a state where interconnection members are connected to the solar cell according to the second embodiment.

FIG. 14 is a schematic cross-sectional diagram of a solar cell according to a third embodiment of the invention.

FIG. 15 is a schematic cross-sectional diagram illustrating a step of connecting interconnection members to the solar cell according to the third embodiment.

FIG. 16 is a schematic cross-sectional diagram illustrating a state where the interconnection members are connected to the solar cell according to the third embodiment.

### DETAILED DESCRIPTION OF EMBODIMENTS

Descriptions are provided hereinbelow for embodiments based on the drawings. In the respective drawings referenced herein, the same constituents are designated by the same reference numerals and duplicate explanation concerning the same constituents is omitted. All of the drawings are provided to illustrate the respective examples only. In addition, it should be noted that the drawings are schematic and ratios of dimensions and the like are different from actual ones. Therefore, specific dimensions and the like should be determined in consideration of the following description. Moreover, the drawings also include portions having different dimensional relationships and ratios from each other.

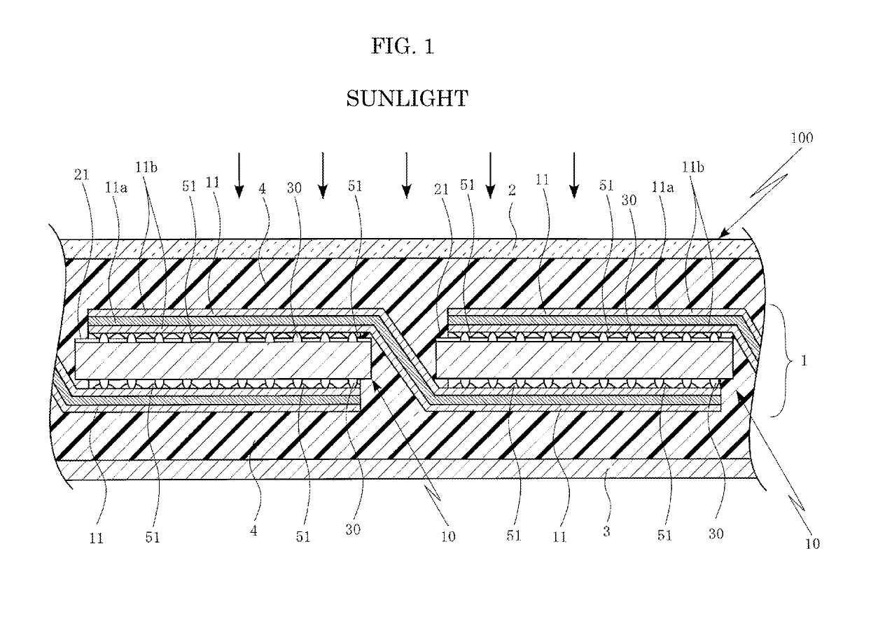

FIG. 1 is an enlarged side cross-sectional view of solar cell module 100 according to a first embodiment.

Solar cell module 100 includes solar cell strings 1, light-receiving surface protection member 2, back surface protection member 3, and sealant 4. Solar cell module 100 is formed in such a manner that each solar cell string 1 between light-receiving surface protection member 2 and back surface protection member 3 is encapsulated with sealant 4.

Solar cell string 1 includes solar cells 10 and interconnection members 11. Solar cell string 1 is formed by connecting solar cells 10 one another by using interconnection members 11.

Each solar cell 10 includes a light-receiving surface on which sunlight is made incident and a back surface opposite from the light-receiving surface. The light-receiving surface of solar cell 10 includes electrodes and the back surface of solar cell 10 includes electrodes. The structure of solar cell 10 is described later.

Each interconnection member 11 is connected to the electrode on the light-receiving surface of one of solar cells 10 and the electrode on the back surface of another one of solar cells 10 next to the one solar cell 10. This electrically connects solar cells 10 next to each other.

Light-receiving surface protection member 2 is arranged on the light-receiving side of sealant 4 and protects a front surface of solar cell module 100. Transparent and water-blocking glass, transparent plastic or the like may be used as light-receiving surface protection member 2.

Back surface protection member 3 is arranged on the back side of sealant 4 and protects a back surface of solar cell module 100. A resin film made of polyethylene terephthalate (PET) or the like, a laminated film with an aluminum (Al) foil sandwiched between resin films, or the like may be used as back surface protection member 3.

Sealant 4 encapsulates solar cell string 1 between light-receiving surface protection member 2 and back surface protection member 3. A transparent resin such as ethylene-vinyl acetate (EVA), ethylene-ethylacrylate copolymer (EEA), polyvinyilbutyral (PVB), silicone, urethane, acryl, or epoxy may be used as sealing material 4.

Note that an aluminum (Al) frame (not shown) may be provided along an outer periphery of solar cell module 100 having the aforementioned configuration. In addition, a terminal box may be provided on back surface protection member 3.

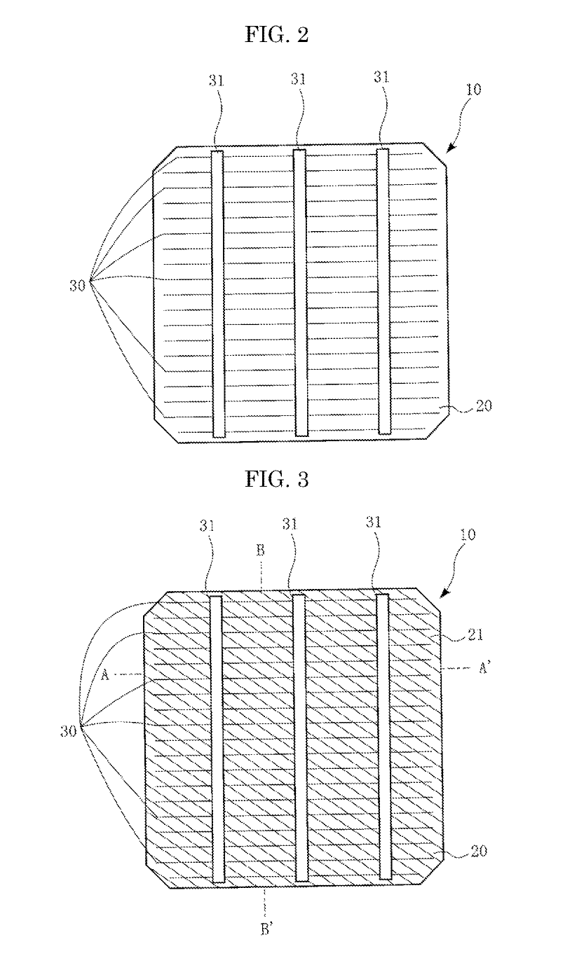

Next, a description is provided hereinbelow for a structure of each solar cell 10 based on FIGS. 2 and 3. FIG. 2 is a plan view of solar cell 10 in a state before a coating film is formed on an entire light-receiving surface of a photoelectric conversion body of solar cell 10. FIG. 3 is a plan view of solar cell 10 including the coating film formed on the entire light-receiving surface of the photoelectric conversion body.

As shown in FIG. 2, solar cell 10 includes: photoelectric conversion body 20 having a front surface and a back surface; finger electrodes 30 and bus bar electrodes 31 all of which are provided on the front surface of photoelectric conversion body 20; and finger electrodes 30 and bus bar electrodes 31 all of which are provided on the back surface of photoelectric conversion body 20. In this embodiment, finger electrodes 30 and bus bar electrodes 31 on the front surface of solar cell 10 form a front-side electrode of solar cell 10, and finger electrodes 30 and bus bar electrodes 31 on the back surface of solar cell 10 form a back-side electrode of solar cell 10.

Photoelectric conversion body 20 generates carriers by receiving sunlight. Here, the term “carriers” refers to holes and electrons generated by absorbing sunlight by photoelectric conversion body 20. Photoelectric conversion body 20 has therein an n-type region and a p-type region, and a semiconductor junction is formed at an interface between the n-type region and the p-type region. Photoelectric conversion body 20 may be formed by using a semiconductor substrate formed by a semiconductor material including a crystalline semiconductor material such as single-crystalline silicon or multi-crystalline silicon, or a compound semiconductor material such as GaAs or InP. In photoelectric conversion body 20, an intrinsic amorphous silicon layer is inserted between a single-crystalline silicon layer and an amorphous silicon layer which are of mutually opposite conductivity types, for example. For use of solar cells each including photoelectric conversion body 20, disadvantages of interfaces therebetween are reduced, and a characteristic of a heterojunction interface is improved.

Finger electrodes 30 collect the carriers from photoelectric conversion body 20. As shown in FIGS. 2 and 3, finger electrodes 30 are formed in lines on the front surface of photoelectric conversion body 20. Finger electrodes 30 are formed in parallel approximately on the entire front surface of photoelectric conversion body 20. Finger electrodes 30 may be formed by using a resin material as a binder and a conductive paste including conductive particles such as silver particles as a filler. Here, as shown in FIG. 1, finger electrodes 30 are formed also on the back surface of photoelectric conversion body 20 in the same manner as on the front surface of photoelectric conversion body 20.

Bus bar electrodes 31 collect the carriers from finger electrodes 30. As shown in FIGS. 2 and 3, bus bar electrodes 31 are formed on the front surface of photoelectric conversion body 20 in such a manner as to cross finger electrodes 30. Bus bar electrodes 31 may be formed by using a conductive paste including a resin material as a binder and conductive particles such as silver particles as a filler, like finger electrodes 30. Here, as shown in FIG. 1, bus bar electrodes 31 are formed also on the back surface of photoelectric conversion body 20 in the same manner as on the front surface of photoelectric conversion body 20. Finger electrodes 30 and bus bar electrodes 31 may be formed by screen printing using a silver paste or another method such as an evaporation method, a spattering method or an electroplating method.

Here, the numbers of bus bar electrodes 31 on the front surface and the back surface of photoelectric conversion body 20 may be set appropriately in consideration of the size or the like of photoelectric conversion body 20. Each solar cell 10 according to this embodiment includes three bus bar electrodes 31.

Regions of the front surface of photoelectric conversion body 20 which are not covered with bus bar electrodes 30 and 31 and the like serve as the light-receiving surface of photoelectric conversion body 20.

Meanwhile, coating film 21 is provided on approximately the entire light-receiving surface of photoelectric conversion body 20 in this embodiment, except at least a part of bus bar electrode 31 on the light-receiving side of photoelectric conversion body 20.

Coating film 21 is a thin film for providing various functions to the light-receiving surface of photoelectric conversion body 20 of solar cell 10. A material of coating film 21 is selected so that coating film 21 can be provided with required functions such as AR (antireflection), UV absorption, and moisture-proof effects. For example, coating film 21 prevents the light-receiving surface of photoelectric conversion body 20 from being exposed on the light-receiving side of solar cell 10 to thereby prevent damage to the light-receiving surface.

Coating film 21 also blocks the light-receiving surface of photoelectric conversion body 20 (i.e., regions where the front surface of photoelectric conversion body 20 is not covered with finger and bus bar electrodes 30 and 31 and the like) from the air. This prevents pn semiconductor junction of photoelectric conversion body 20 from being deteriorated due to ionization, of structure materials of photoelectric conversion body 20, caused by moisture in the air. As described above, coating film 21 protects the light-receiving surface of photoelectric conversion body 20 of solar cell 10 from damage and moisture to thereby prevent deterioration of photoelectric conversion efficiency of solar cell 10.

As coating film 21, a transparent resin may be used such as EVA, PVA, PVB, silicone, acryl, epoxy, or polysilazane. In addition, an additive such as silicon oxide, aluminum oxide, magnesium oxide, titanium oxide, or zinc oxide may be added to the resin. For example, an acrylic resin to which silicon oxide is added may be used as coating film 21. Further, a transparent inorganic film may also be used as coating film 21.

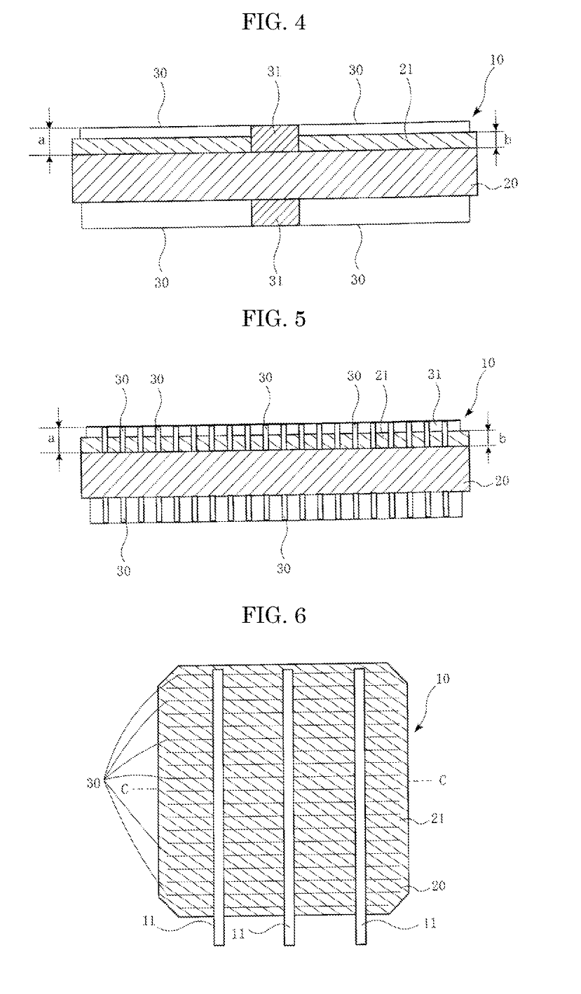

With reference to FIGS. 4 and 5, a description is provided for a relationship between a thickness of coating film 21 and a thickness of finger electrodes 30 and a thickness of bus bar electrodes 31. FIG. 4 is a cross-sectional view of solar cell taken along the A-A′ line of FIG. 3 and FIG. 5 is a cross-sectional view of solar cell 10 taken along the B-B′ line of FIG. 3. In this embodiment, coating film 21 is formed to have thickness (b) less than thickness (a) of finger electrodes 30 and bus bar electrodes 31, as shown in FIGS. 4 and 5. For example, if finger electrodes 30 and bus bar electrodes 31 have a thickness of approximately 25 μm to 70 μm, coating film 21 is formed to have a thickness of approximately 1 μm to 10 μm.

As shown in FIGS. 3 to 5, coating film 21 is formed in such a manner as to coat approximately the entire front surface of photoelectric conversion body 20 and to be in contact with both side edges of finger electrodes 30 and bus bar electrodes 31. In this embodiment, coating film 21 is provided to substantially the entire light-receiving surface of photoelectric conversion body 20 in such a manner as to have a thickness less than a part of electrodes 30 and 31 (bus bar electrodes 31 in this embodiment). Coating film 21 is consequently provided substantially on the entire light-receiving surface of photoelectric conversion body 20 in a state where coating film 21 is in contact with both side edges of finger electrodes 30 and both side edges of bus bar electrode 31. In addition, even if apart of bus bar electrode (s) 31 is coated with coating film 21, a different part thereof is exposed without being coated with coating film 21, so that bus bar electrode 31 is electrically connectable to corresponding interconnection member 11. Here, although the entire front surface of each finger electrode 30 is preferably coated with coating film 21, a part of finger electrode 30 may be uncoated with coating film 21.

In this embodiment, each interconnection member 11 includes copper foil plate 11a serving as a core material, and is provided with soft conduction layer 11b which is a plated layer or the like on a front surface of copper foil plate 11a. Interconnection member 11 includes copper foil plate 11a and soft conduction layer 11b made of solder with which the front surface of copper foil plate 11a is plated.

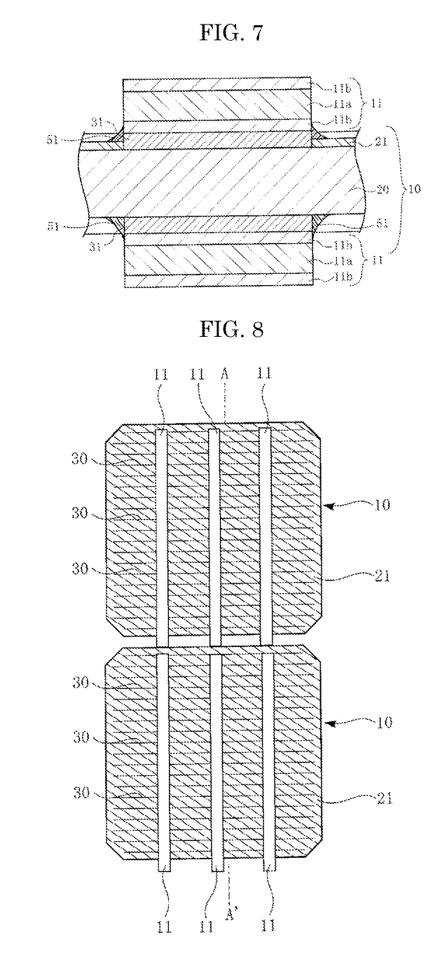

In this embodiment, each bus bar electrode 31 is connected to corresponding interconnection member 11 by using a resin adhesive such as a resin adhesive film. Electrical connection between bus bar electrode 31 and interconnection member 11 is made in the exposed part of bus bar electrode 31. As shown in FIGS. 6 and 7, each interconnection member 11 and solar cell 10 are mechanically connected by using resin adhesive 51. Solar cell 10 is provided with coating film 21 applied to approximately the entire light-receiving side of solar cell 10, and the mechanical strength is maintained by bonding coating film 21 and an end portion of interconnection member 11 to each other by using fillet-shaped resin adhesive 51 as shown in FIG. 7. Resin adhesive 51 provides sufficient bonding even when a member to be bonded is a resin, and thus the same holds true for coating film 21.

In this embodiment, since a coating film is not provided on the back side of solar cell 10, the back surface of solar cell 10 and interconnection member 11 are mechanically connected to each other by using fillet-shaped resin adhesive 51.

A resin adhesive sheet, for example, having a width equal to or narrower than interconnection member 11 is used as resin adhesive 5, and is placed on bus bar electrode 31. An anisotropic conductive resin adhesive, for example, is used as the resin adhesive sheet.

The anisotropic conductive resin adhesive includes at least a resin adhesive component and conductive particles dispersed therein. The resin adhesive component is formed by a compound containing a thermosetting resin, and for example, an epoxy resin, a phenoxy resin, an acrylic resin, a polyimide resin, a polyamide resin, polycarbonate resin, a urethane resin or the like may be used. Only one type of or combined two or more types of the thermosetting resins are used. It is preferable to use one or more types of the thermosetting resins selected from the group of the epoxy resin, the phenoxy resin, and the acrylic resin.

Metal particles or conductive particles, for example, are used as the conductive particles, the metal particles including gold particles, silver particles, copper particles, and nickel particles, the conductive particles being obtained by coating surfaces of conductive nuclear particles such as gold, copper, and nickel plating particles, or insulating nuclear particles with a conductive layer such as a metal layer.

Next, a description is provided for a method of manufacturing a solar cell module according to the first embodiment of the invention.

Firstly, photoelectric conversion body 20 is formed. Next, finger electrodes 30 and bus bar electrodes 31 are formed on the front surface of photoelectric conversion body 20. Similarly, finger electrodes 30 and bus bar electrodes 31 are formed on the back surface of photoelectric conversion body 20, thereby obtaining solar cell 10.

The light-receiving surface of photoelectric conversion body 20 is a region of the front surface of photoelectric conversion body 20 other than finger and bus bar electrodes 30 and 31 (light-receiving side electrodes 30 and 31) on the front surface of photoelectric conversion body 20. In other words, the light-receiving surface of each solar cell 10 includes the light-receiving surface of photoelectric conversion body 20 and light-receiving side electrodes 30 and 31.

Next, coating film 21 is applied to the entire light-receiving surface of solar cell 10.

As a method of applying coating film 21, a method (for example, offset printing, roll-to-roll coating or the like) may be used with which a liquid or gel transparent resin applied to a circumferential surface of a roller is transferred onto the entire light-receiving surface of solar cell 10 while rolling the roller. Note that the method of applying coating film 21 is not limited to these, and another method may be used.

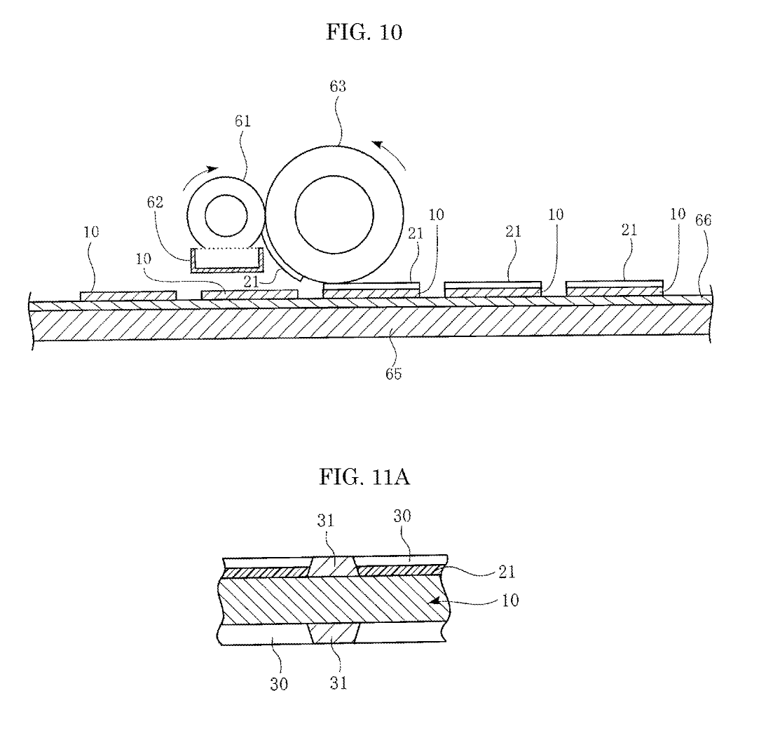

The method of applying coating film 21 is specifically described based on FIG. 10. FIG. 10 is a schematic diagram illustrating a method of forming a coating film according to the first embodiment of the invention.

Recesses in a particular pattern are formed in a circumferential surface of cylindrical printing cylinder 61. Note that the particular pattern refers to a shape provided for a coating material to be applied to the entire light-receiving surface of solar cell 10. For example, the particular pattern is formed to match the size of the entire light-receiving surface of solar cell 10.

Resin tank 62 stores a liquid or gel resin. Rotating printing cylinder 61 is dipped in the liquid or gel resin in resin tank 62. The resin is removed from regions other than the recesses in the circumferential surface of printing cylinder 61, thus being left only in the recesses. Here, the circumferential surface of printing cylinder 61 may have no level difference between the region where the resin is removed and the region where the resin is left. Specifically, these regions may be chemically separated from each other.

Cylindrical blanket 63 includes an elastic member on a circumferential surface thereof. Blanket 63 rotates in a direction reverse to a rotation direction of printing cylinder 61 with the circumferential surface of blanket 63 in contact with the circumferential surface of printing cylinder 61. The resin left in the recesses of printing cylinder 61 is transferred to the circumferential surface of blanket 63. At this time, the resin transferred to the circumferential surface of blanket 63 has the particular pattern for application to the entire light-receiving surface of solar cell 10.

Conveyor 65 conveys, in a certain conveyance direction, solar cells 10 placed on placement stage 66 which is a flat plate. Each solar cell 10 is placed on placement stage 66 with the light-receiving surface thereof facing upward. A belt conveyor or the like may be used as conveyor 65. Solar cell 10 placed on placement stage 66 passes under rotating blanket 63, while being conveyed by conveyor 65. At this time, particular-pattern resin 64 onto the circumferential surface of blanket 63 is transferred onto the light-receiving surface of solar cell 10. The liquid or gel particular-pattern resin 64 transferred onto the light-receiving surface of solar cell 10 is hardened as being dried. Thereby, coating film 21 is formed on the light-receiving surface of solar cell 10.

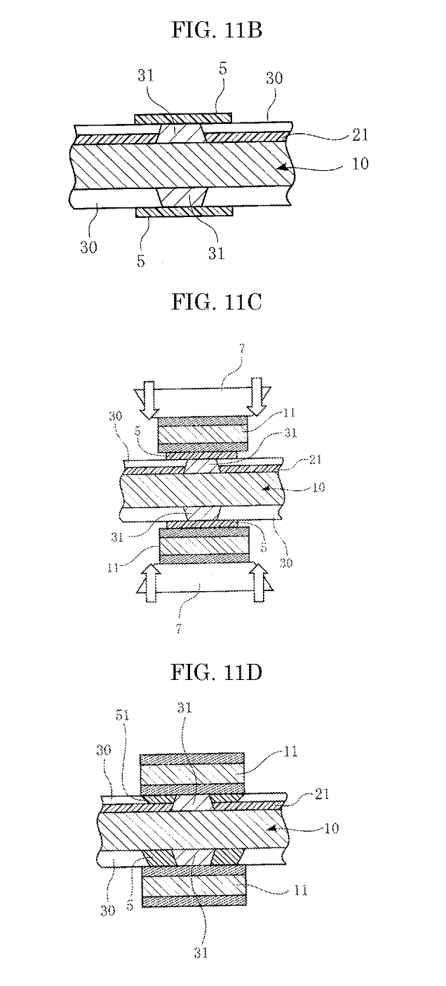

With the aforementioned step, solar cell 10 as shown in FIG. 11A is prepared.

Next, solar cells 10 next to each other are electrically connected to one another by using interconnection members 11. Specifically, each interconnection member 11 is placed on bus bar electrodes 31 on the front and back surfaces of the respective first and second ones of solar cells 10, with anisotropic conductive resin adhesive 5 placed between each bus bar electrode 31 and interconnection member 11. In order to connect one end side of interconnection member 11 to corresponding bus bar electrode 31 on the upper side of the first solar cell 10 and to connect the other end side of interconnection member 11 corresponding bus bar electrode 31 on the lower side of the second solar cell 10 next to the first solar cell 10.

For example, anisotropic conductive resin adhesive 5 is firstly placed on bus bar electrodes 31, 31 of solar cells 10, respectively, as shown in FIG. 11B.

Thereafter, as shown in FIG. 11C, for example, interconnection member 11 is arranged on bus bar electrodes 31 on the light-receiving surface and back sides of solar cells 10, respectively, with anisotropic conductive resin adhesive 5 placed between each bus bar electrode 31 and interconnection member 11. In this state, each solar cell 10 is placed between heat blocks 7 and pressed between heat blocks 7 at a pressure of approximately 0.05 MPa to 1.00 MPa, for example. This causes interconnection member 11 to be pressed onto each solar cell 10 with resin adhesive 5 placed in between. Then, heat blocks 7 are heated at such a high temperature that a resin adhesive component of resin adhesive 5 is thermally hardened, for example, at a temperature between 120° C. and 200° C. inclusive to compression-bond and fix interconnection member 11. Then, the thermosetting causes resin adhesive 5 to turn into fillet-shaped resin adhesive 51, as shown in FIG. 11D. Interconnection member 11 is mechanically connected to coating film 21 due to the resin adhesive component of fillet-shaped resin adhesive 51, and interconnection member 11 is electrically connected to bus bar electrodes 31, 31, with the conductive particles of fillet-shaped resin adhesive 51 placed in between or in direct contact therebetween.

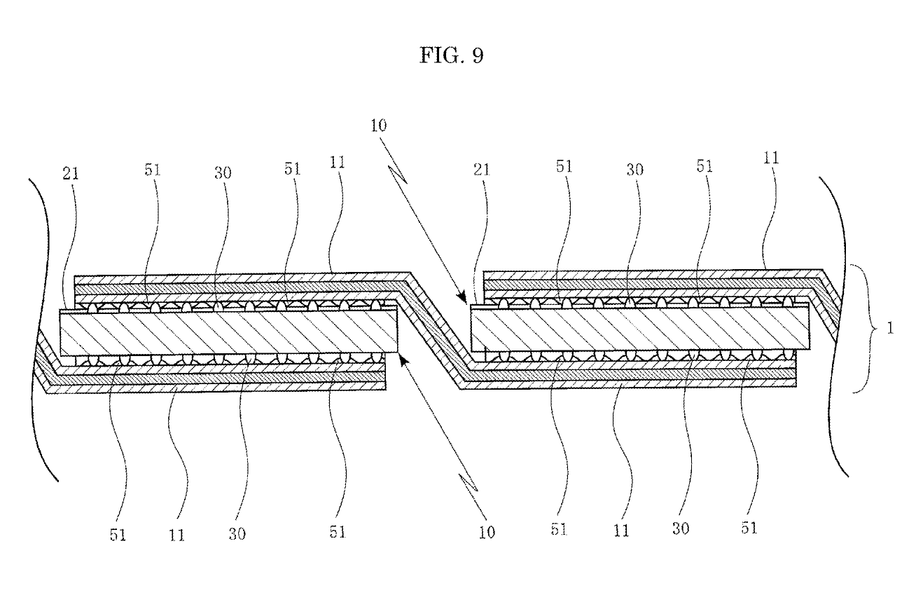

Likewise, as shown in FIGS. 8 and 9, the second solar cell 10 is placed on interconnection member 11 to be compression-bonded at a low pressure, and is bonded in the aforementioned steps. After a desired numbers of solar cells 10 are bonded to one another, solar cell string 1 is formed.

Next, sealant 4, solar cells 10 connected to one another by interconnection members 11, sealant 4, and back surface protection member 3 are placed in this order on light-receiving surface protection member 2, so that a laminate is formed.

Then, solar cell module 100 shown in FIG. 1 is manufactured by heating and compression-bonding the laminate in a vacuum atmosphere.

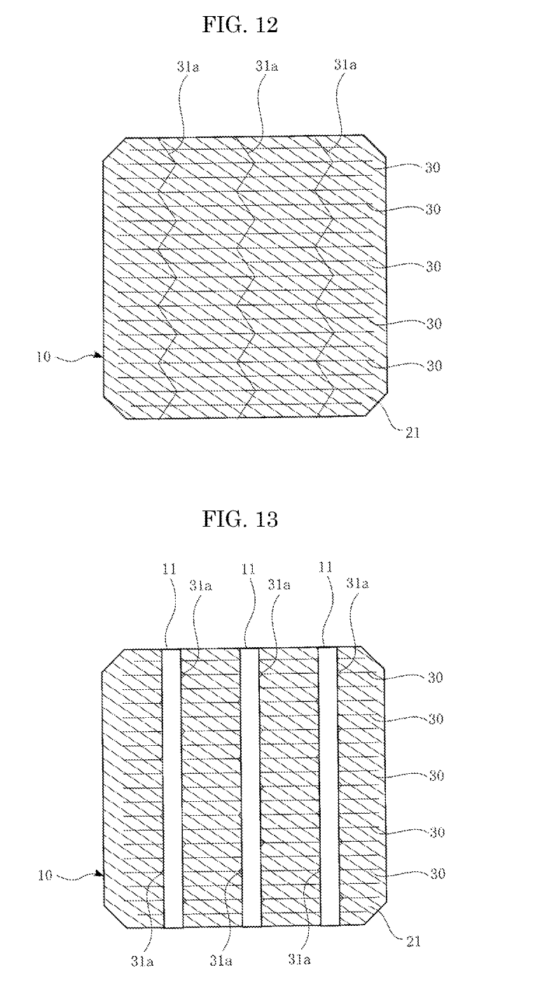

Next, a description is provided for a second embodiment of the invention. In the first embodiment described above, bus bar electrodes 31 are formed to have approximately the same width as the width of interconnection members 11. Bus bar electrodes 31a shown in FIG. 12 are each formed into a zig-zag shape to have approximately the same width as the width of finger electrodes 30. Each bus bar electrode 31a is electrically connected to all of finger electrodes 30. Bus bar electrode 31a is arranged in a zig-zag manner to have a region width slightly larger than the width of corresponding interconnection member 11 in consideration of a mechanical accuracy error of attaching position of an interconnection member (a tab) and a positional accuracy error of a bus bar electrode.

In addition, by using a smaller number of finger electrodes 30 on the light-receiving side than the number thereof on the back side, light incidence blocking can be reduced. Bus bar electrodes 31a are provided also on the back side. Bus bar electrodes 31a on the back side are formed into a zig-zag shape like bus bar electrodes 31a on the light-receiving side. Each bus bar electrode 31a on the back side is connected all of finger electrodes 30 thereon. Each bus bar electrode 31a on the light-receiving side and corresponding bus bar electrode 31a on the back side are formed in a overlapping position.

Coating film 21 is provided on an entire surface of the light-receiving surface of each solar cell 10 in such a manner that at least a part of bus bar electrode(s) 31a on the light-receiving side is exposed.

Also in the second embodiment, coating film 21 is formed to have a thickness less than a thickness of finger electrodes 30 and bus bar electrodes 31. Finger electrodes 30 and bus bar electrodes 31 have the thickness of approximately 25 μm to 70 μm, and coating film 21 have the thickness of approximately 1 μm to 10 μm.

Like the first embodiment described above, coating film 21 is formed in such a manner as to coat approximately an entire front surface of photoelectric conversion body 20 and to be in contact with both widthwise sides of finger electrodes 30 and both widthwise sides of bus bar electrodes 31a.

Coating film 21 is provided to an entire light-receiving surface of photoelectric conversion body 20, in such a manner as to have a thickness less than a part of electrodes 30 and 31a. The coating film 21 is provided to the light-receiving surface of photoelectric conversion body 20 in such a manner as to be in contact with both side edges of finger electrodes 30 and both side edges of bus bar electrodes 31a. Although a part of the front surface of bus bar electrode(S) 31a on the light-receiving side is coated with coating film 21, a different part thereof is exposed without being coated with coating film 21, so that bus bar electrode 31a is connectable to corresponding interconnection member 11. Here, although the entire front surface of finger electrode (s) 30 is preferably coated with coating film 21, a part of finger electrode(s) 30 may be uncoated with coating film 21.

Next, a description is provided for a method of manufacturing a solar cell module by using solar cells 10 described above. In solar cell module 100, interconnection members 11 are electrically and mechanically connected to finger electrodes 30 and bus bar electrodes 31a on the light-receiving side and to finger electrodes 30 and bus bar electrodes 31a on the back side. Resin adhesive 5 is used to connect interconnection members 11 to finger electrodes 30 and bus bar electrodes 31a on the front and back sides.

Firstly, resin adhesive 5 is placed between each interconnection member 11 and corresponding bus bar electrode 31a on the light-receiving side of solar cells 10 and interconnection member 11 and corresponding bus bar electrode 31a on the back side. Resin adhesive 5 used for compression bonding preferably has a width equivalent to or slightly less than the width of interconnection member 11 to be connected. In this embodiment, three interconnection members 11 are used as shown in FIG. 13. Accordingly, three resin adhesives 5 having the width equivalent to the width of interconnection members 11 are provided on bus bar electrodes 31a of solar cell 10 at positions where interconnection members 11 are to be bonded. Note that resin adhesives 5 wider than interconnection members 11 may be used, as long as resin adhesives 5 are transparent even after hardening.

Like the first embodiment described above, each interconnection member 11 includes a thin copper plate plated with Sn as a coating layer. The coating layer forms a soft conductive layer softer than finger electrodes 30 and bus bar electrodes 31a.

Interconnection member 11 is subjected to heating processing while being pressed against resin adhesive 5, so that an adhesive layer of resin adhesive 5 is thermally hardened. Thereby, on the light-receiving side, interconnection member 11 is electrically connected to corresponding bus bar electrode 31a directly or via the conductive particles in resin adhesive 5 and is are mechanically connected to coating film 21 with resin adhesive 5. The same processing is performed on the back side.

In the second embodiment, a part of each zig-zag bus bar electrode 31a is provided at an area where interconnection member 11 is to be connected. Bus bar electrodes 31a, 31a thus provided enable favorable electrical connection with interconnection members 11. In regions where finger electrodes 30, 30 are not provided, connection is made between each bus bar electrode 31a and corresponding interconnection member 11, so that the strength of bonding with interconnection member 11 and electrical characteristics are enhanced.

Also in the second embodiment, an anisotropic conductive or insulating resin adhesive may be used as resin adhesive 5. If the insulating resin adhesive is used, parts of the front surfaces of finger electrodes 30 and bus bar electrodes 31a are in direct contact with surfaces of interconnection members 11 to thereby make electrical connection. In this case, it is preferable that each interconnection member 11 includes conductive films made of Sn, solder or the like softer than finger and bus bar electrodes 30 and 31a on the front and back side and covering a conductive body such as a copper foil plate and that thereby the connection be made in such a manner that finger and bus bar electrodes 30 and 31a partially dig into the conductive films of interconnection member 11.

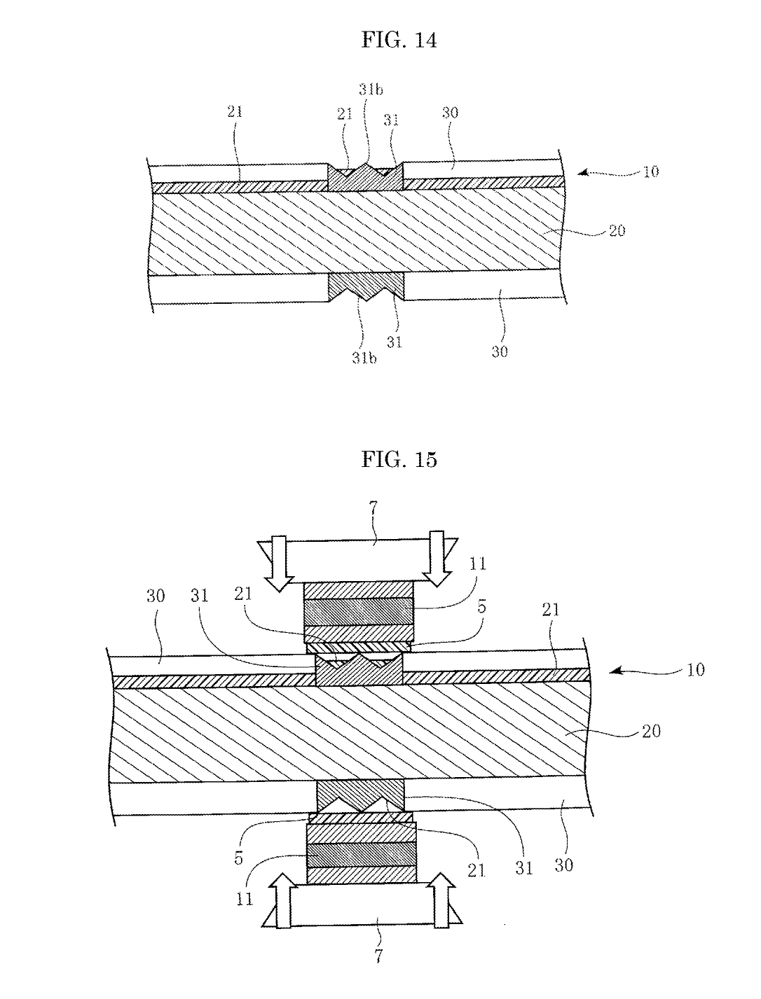

Next, a description is provided for a third embodiment of the invention based on FIGS. 14 to 16.

In the third embodiment, each bus bar electrode 31 has a finely textured front surface. When being formed by using the silver paste by the screen printing as described above, each bus bar electrodes 31 has the front surface having a texture or indentations having 1 μm to 20 μm high and 40 μm to 80 μm wide due to a mesh plate used in the screen printing.

In the third embodiment, approximately the entire light-receiving surface of each solar cell 10 including the front surfaces of bus bar electrodes 31 and finger electrodes 30 is coated with coating film 21 in such a manner that the film thickness of coating film 21 is less than the height of the texture, as shown in FIG. 14. The thickness of the coating material for coating film 21 that is applied to the entire surface is less than the height of the texture in the front surface of each bus bar electrode 31. For this reason, the coating material of coating film 21 remains in recessed portions of the textured front surface of bus bar electrode 31, so that protruding portions 31b of the textured front surface of bus bar electrode 31 are exposed from coating film 31.

Coating film 21 is provided on an entire surface of photoelectric conversion body 20 and not provided at protruding portion 31b of bus bar electrode 31. In this embodiment, resin adhesive 5 is used to connect protruding portion 31b of bus bar electrode 31 and corresponding one of interconnection members 11, thus leading to favorable connection therebetween. Each interconnection member 11 includes copper foil plate 11a serving as the core material, and soft conduction layer 11b which is the plated layer or the like on copper foil plate 11a.

Finger and bus bar electrodes 30 and 31 may be formed by screen printing using a silver paste or another method such as the electroplating method, the spattering method or the evaporation method. In the case of forming electrodes by the electroplating method, a non-gloss plating method enables formation of the texture in the front surface of each electrode. In the case of forming electrodes by the spattering method or the evaporation method, the texture is not formed in the front surface of each electrode in the method. In this case, however, the texture may be formed by filing the front surface of each electrode or the like.

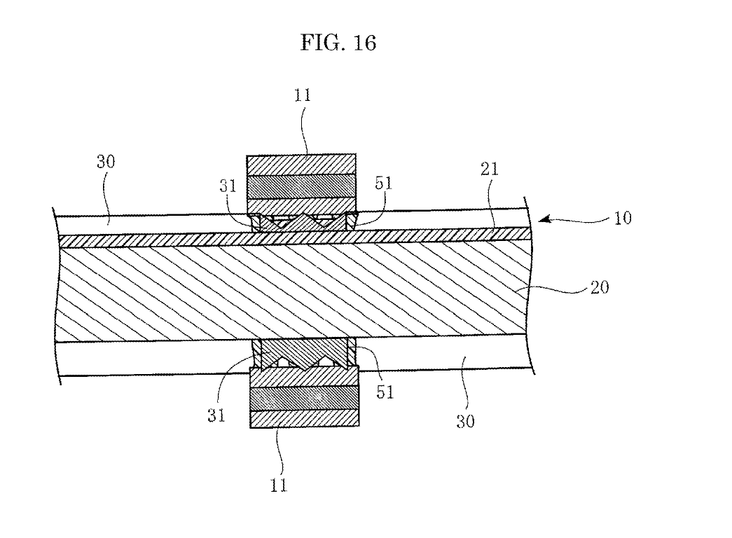

A solar cell module may also be manufactured by using solar cells 10 in the third embodiment described above in the same manner as in the method of manufacturing the solar cell module in the first embodiment. In other words, to manufacture the solar cell module in the third embodiment, interconnection members 11 are electrically and mechanically connected to finger electrodes 30 and bus bar electrodes 31 on the light-receiving side and to finger electrodes 30 and bus bar electrodes 31 on the back side, as shown in FIG. 15. To connect interconnection members 11 to finger electrodes 30 and bus bar electrodes 31 on the front and back sides, resin adhesive 5 is used. In the third embodiment, as shown in FIG. 16, each interconnection member 11 includes the conductive film which is made of Sn, solder or the like softer than finger and bus bar electrodes 30 and 31 on the front side and the back side and covers the conductive body such as the copper foil plate. Thereby, the connection is made in such a manner that finger and bus bar electrodes 30 and 31 partially dig into the conductive films of interconnection members 11.

First to the third embodiments describe the case where the coating film is formed on the light-receiving surface. The invention is not limited to this, and is applicable to a solar cell including coating films formed on the light-receiving surface and the back surface of the solar cell.

Further, interconnection members 11 are not limited to ones coated with solder. Interconnection members 11 coated with another type of conductive film such as an Ag coat film may be used.

The coating film is formed by the offset printing or the roll-to-roll coating in First to the third embodiments described above, but is not limited to this. Specifically, the coating film may be formed by another application method such as a spray method, the screen printing or a dip method.

Note that an inorganic material or the like may be used as the coating film by the evaporation method or the like. In this case, forming a film having a thickness less than the height of the texture of the front surface of the electrode makes it possible to deposit the material of the coating film in the recessed portions and to expose the protruding portions of the front surface of the electrode. This makes it possible to partially expose the front surface of the electrode without using a mask and electrically connect the electrode with the interconnection member.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell module comprising:
solar cells; and
an interconnection member configured to connect the solar cells, wherein
one of the solar cells has
a light-receiving surface including a
light-receiving side electrode,
a back surface including a back-side electrode, and
a coating film formed on substantially the entire light-receiving surface except at least a part of the light-receiving side electrode in such a manner that the at least part is exposed from the coating film,
the interconnection member is electrically connected to the part of the electrode exposed from the coating film and is mechanically connected to the coating film.

2. The solar cell module according to claim 1, wherein
the coating film has a film thickness less than a thickness of the at least part of the electrode.

3. The solar cell module according to claim 2, wherein
the coating film is formed by applying a coating material to the entire light-receiving surface including the light-receiving side electrode.

4. The solar cell module according to claim 3, wherein
the coating material includes a resin.

5. The solar cell module according to claim 1, further comprising a resin adhesive mechanically connecting the interconnection member and the solar cells.

6. The solar cell module according to claim 5, wherein
the resin adhesive includes a resin adhesive component and conductive particles dispersed in the resin adhesive component.

7. The solar cell module according to claim 1, wherein
the electrode is provided with a texture in a front surface thereof, and
the coating film has a film thickness less than a depth of the texture.

8. A solar cell comprising:
a photoelectric conversion body having a first surface and a second surface provided on an opposite side from the first surface;
an electrode formed on the first surface; and
a coating layer coating the first surface of the photoelectric conversion body and being in contact with both side edges of the electrode, with exposing at least a part of the electrode from the coating layer.

9. The solar cell according to claim 8, wherein an interconnection member connecting the solar cell and another solar cell is connected to the part of the electrode exposed from the coating layer.

10. The solar cell according to claim 8, wherein the coating layer has a thickness less than a thickness of the part of the electrode exposed from the coating layer.

11. The solar cell according to claim 8, wherein
the electrode includes a texture in a front surface, and
the coating layer has a thickness less than a depth of the texture of the electrode.
